(19) United States
(12) Patent Application Publication
(10) Pub. No.: US 2026/0370153 A1
(43) Pub. Date: Nov. 19, 2026

(54) Power Conversion Device

(71) Applicant: Mitsubishi Electric Corporation, Chiyoda-ku, Tokyo (JP)

(72) Inventors: Hirokazu NAKABAYASHI, Chiyoda-ku, Tokyo (JP); Yujiro SAKURAI, Chiyoda-ku, Tokyo (JP)

(73) Assignee: Mitsubishi Electric Corporation, Chiyoda-ku, Tokyo (JP)

(21) Appl. No.: 19/121,878

(22) PCT Filed: Dec. 7, 2023
(86) PCT No.: PCT/JP2023/043898

§ 371 Date: Apr. 17, 2025

(30) Foreign Application Priority Data
Dec. 15, 2022 (JP) 2022-199919

(51) Int. Cl. H02M 7/00; H02M 7/5387; H05K 7/20

(52) U.S. Cl. CPC H02M 7/003; H02M 7/5387; H05K 7/20945

(57) ABSTRACT

A power conversion device includes a capacitor element, a switching element, a wiring member, a cooling body, and a thermally conductive insulating member. The wiring member is connected to the capacitor element and the switching element. On the cooling body, the capacitor element and the switching element are mounted. The thermally conductive insulating member is connected to the cooling body and the wiring member. The wiring member has a first contact portion and a second contact portion. The wiring member is connected to the capacitor element at the first contact portion and connected to the switching element at the second contact portion. Thermal resistance of the wiring member from the first contact portion to the thermally conductive insulating member is lower than thermal resistance of the wiring member from the second contact portion to the thermally conductive insulating member.

### TECHNICAL FIELD

The present disclosure relates to a power conversion device.

### BACKGROUND ART

A power conversion device such as a voltage-type inverter to convert direct-current (DC) power into alternating-current (AC) power has recently been used not only in an air-conditioner, a machine tool, a railway driving apparatus, and an elevator but also in a renewable energy power conditioner and an electric vehicle. A configuration including a cooler on which a capacitor element and a switching element are mounted, a wiring member connected to the capacitor element and the switching element, and a thermally conductive insulating member connected to the wiring member and the cooler has been known as the configuration of such a power conversion device (see, for example, Japanese Patent Laying-Open No. 2017-188998).

### CITATION LIST

### Patent Literature

PTL 1: Japanese Patent Laying-Open No. 2017-188998

### SUMMARY OF INVENTION

### Technical Problem

The power conversion device as above, however, is to be applied to a wide variety of products, and hence the power conversion device has been demanded to be smaller in size. In particular, reduction in size of the capacitor element high in proportion of its volume in the power conversion device has been demanded, and in order to realize the reduction in size, improvement in capability to cool the capacitor element has been an issue.

The present disclosure was made to solve the problem as above, and an object of the present disclosure is to provide a power conversion device improved in capability to cool a capacitor element.

### Solution to Problem

A power conversion device according to the present disclosure includes a capacitor element, a switching element, a wiring member, a cooling body, and a thermally conductive insulating member. The wiring member is electrically connected to the capacitor element and the switching element. On the cooling body, the capacitor element and the switching element are mounted. The thermally conductive insulating member is connected to the cooling body and the wiring member. The wiring member has a first contact portion and a second contact portion. The wiring member is connected to the capacitor element at the first contact portion. The wiring member is connected to the switching element at the second contact portion. Thermal resistance of the wiring member in an area from the first contact portion to the thermally conductive insulating member is lower than thermal resistance of the wiring member in an area from the second contact portion to the thermally conductive insulating member.

### Advantageous Effects of Invention

According to the above, a power conversion device improved in capability to cool a capacitor element can be obtained.

### BRIEF DESCRIPTION OF DRAWINGS

FIG. 1 is a circuit diagram of a power conversion device according to a first embodiment.

FIG. 2 is a perspective view of the power conversion device according to the first embodiment.

FIG. 3 is a plan view of the power conversion device according to the first embodiment.

FIG. 4 is a cross-sectional view along a line segment IV-IV in FIG. 3.

FIG. 5 is a cross-sectional view along a line segment V-V in FIG. 3.

FIG. 6 is a plan view showing a modification of the power conversion device according to the first embodiment.

FIG. 7 is a circuit diagram of a power conversion device according to a second embodiment.

FIG. 8 is a perspective view of the power conversion device according to the second embodiment.

FIG. 9 is a plan view of the power conversion device according to the second embodiment.

FIG. 10 is a cross-sectional view along a line segment X-X in FIG. 9.

FIG. 11 is a cross-sectional view along a line segment XI-XI in FIG. 9.

FIG. 12 is a cross-sectional view of a power conversion device according to a third embodiment.

FIG. 13 is a cross-sectional view of the power conversion device according to the third embodiment.

FIG. 14 is a cross-sectional view of a power conversion device according to a fourth embodiment.

FIG. 15 is a cross-sectional view of the power conversion device according to the fourth embodiment.

### DESCRIPTION OF EMBODIMENTS

An embodiment of the present disclosure will be described below. The same or corresponding elements in the drawings below have the same reference characters allotted and description thereof will not be repeated unless otherwise mentioned.

### First Embodiment

### <Configuration of Power Conversion Device>

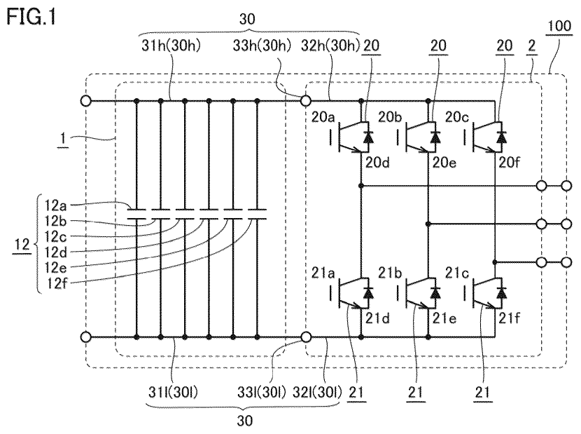

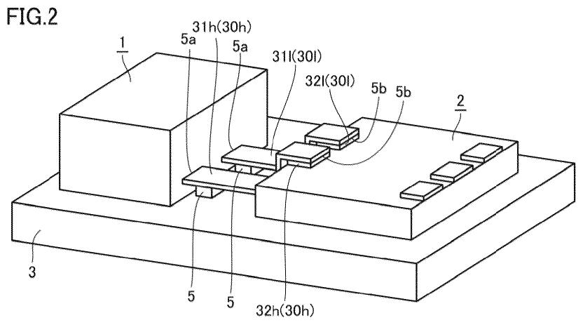

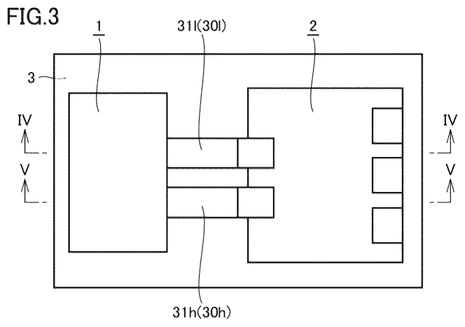

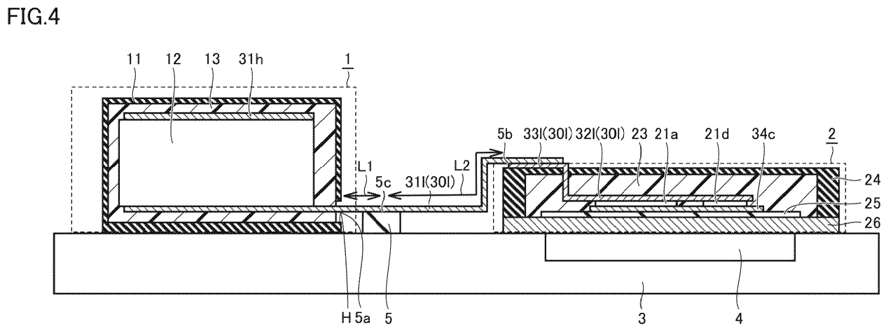

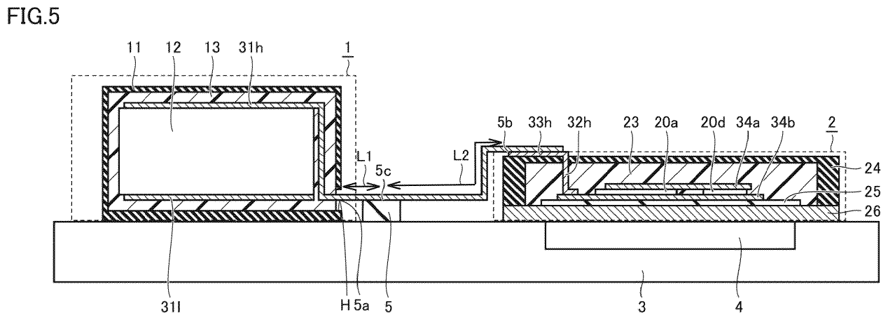

FIG. 1 is a circuit diagram of a power conversion device 100 according to a first embodiment. FIG. 2 is a perspective view of power conversion device 100 according to the first embodiment. FIG. 3 is a plan view of power conversion device 100 according to the first embodiment. FIG. 4 is a cross-sectional view along a line segment IV-IV in FIG. 3. FIG. 5 is a cross-sectional view along a line segment V-V in FIG. 3.

Power conversion device 100 shown in FIGS. 1 to 5 is, for example, power conversion device 100 to convert a DC voltage into an AC voltage and composed of a capacitor module 1 to smoothen a voltage, a power module 2 to convert a direct current (DC) voltage into an alternating current (AC) voltage, and a wiring member 30 electrically connected to capacitor module 1 and power module 2. Wiring member 30 includes a high-potential-side wiring member 30h and a low-potential-side wiring member 30l. High-potential-side wiring member 30h is composed of a capacitor high-potential-side wiring member 31h, a power module high-potential-side wiring member 32h, and semiconductor element wiring members 34a and 34b. Low-potential-side wiring member 30l is composed of a capacitor low-potential-side wiring member 31l, a power module low-potential-side wiring member 32l, and a semiconductor element wiring member 34c.

An electric circuit of power conversion device 100 according to the present first embodiment will initially be described. As shown in FIG. 1, capacitor module 1 includes a capacitor element 12, capacitor high-potential-side wiring member 31h, and capacitor low-potential-side wiring member 31l. Six capacitor elements 12a, 12b, 12c, 12d, 12e, and 12f are arranged as capacitor element 12. Capacitor elements 12a, 12b, 12c, 12d, 12e, and 12f are connected in parallel. Capacitor high-potential-side wiring member 31h is connected to a high potential side of capacitor element 12. Capacitor high-potential-side wiring member 31h is connected to a power module high-potential-side terminal portion 33h on the other end side located at a position opposite to one end connected to the high potential side of capacitor element 12. Capacitor low-potential-side wiring member 31l is connected to a low potential side of capacitor element 12. Capacitor low-potential-side wiring member 31l is connected to a power module low-potential-side terminal portion 33l on the other end side located at a position opposite to one end connected to the low potential side of capacitor element 12.

Though a film capacitor is employed for each of six capacitor elements 12a, 12b, 12c, 12d, 12e, and 12f in the present first embodiment, a capacitor of another type may be employed. Though six capacitor elements 12a, 12b, 12c, 12d, 12e, and 12f are connected in parallel, they may be connected, for example, in series, or may be connected in series-parallel with connection in series and connection in parallel being combined.

In the present first embodiment, an internal circuit of power module 2 is a three-phase full-bridge inverter circuit. Power module 2 includes switching elements 20 and 21, power module high-potential-side wiring member 32h, and power module low-potential-side wiring member 32l. In the present first embodiment, switching elements 20 and 21 are high-potential-side IGBT elements 20a, 20b, and 20c and high-potential-side diode elements 20d, 20e, and 20f of three phases and low-potential-side IGBT elements 21a, 21b, and 21c and low-potential-side diode elements 21d, 21e, and 21f of three phases, respectively. Power module high-potential-side wiring member 32h includes power module high-potential-side terminal portion 33h. Power module high-potential-side wiring member 32h is connected to collector electrodes of high-potential-side IGBT elements 20a, 20b, and 20c on the other end side located at the position opposite to one end including power module high-potential-side terminal portion 33h. High-potential-side diode elements 20d, 20e, and 20f are connected in anti-parallel to high-potential-side IGBT elements 20a, 20b, and 20c, respectively. Power module low-potential-side wiring member 32l includes power module low-potential-side terminal portion 33l. Power module low-potential-side wiring member 32l is connected to emitter electrodes of low-potential-side IGBT elements 21a, 21b, and 21c on the other end side located at the position opposite to one end including power module low-potential-side terminal portion 33l. Low-potential-side diode elements 21d, 21e, and 21f are connected in anti-parallel to low-potential-side IGBT elements 21a, 21b, and 21c, respectively.

Though the internal circuit of power module 2 is the three-phase full-bridge inverter circuit in the present first embodiment, it may be another inverter circuit. For example, the internal circuit of power module 2 may be a multi-level inverter circuit such as a single-phase inverter, a dual three-phase inverter, or a three-level inverter circuit. Though the present first embodiment shows power module 2 including all inverter circuits, power module 2 may be implemented by an individual power element. The power element may be, for example, a MOSFET, other than the IGBT element.

A configuration of power conversion device 100 in the present first embodiment will now be described. As shown in FIGS. 2 to 5, capacitor module 1 and power module 2 are arranged on an upper surface of a cooling body 3. Cooling body 3 should only be able to receive heat generated in capacitor module 1 and power module 2 and to transfer that heat to the outside (for example, a surrounding space), and any feature may be adopted as the cooling body. For example, cooling body 3 should only radiate heat by convection and by radiation to the surrounding space through a surface of cooling body 3. Alternatively, a refrigerant flow channel as will be described later may be provided in cooling body 3, and heat may be transferred to the outside through refrigerant that flows through the refrigerant flow channel. Therefore, cooling body 3 may be, for example, a housing where capacitor module 1 and the power module are accommodated. Alternatively, cooling body 3 may be a member separate from the housing and may be connected to the housing. A material for cooling body 3 may be, for example, a metallic material such as aluminum (Al) or iron (Fe).

As shown in FIGS. 4 and 5, a refrigerant flow channel 4 through which refrigerant such as cooling water flows may be provided at the upper surface of cooling body 3. Power module 2 is arranged directly over refrigerant flow channel 4. By thus arranging power module 2 directly over refrigerant flow channel 4, power module 2 is cooled. In order to more effectively cool capacitor element 12, for example, refrigerant flow channel 4 may be provided directly under capacitor module 1. A method of cooling power module 2 may be air cooling in which gas for cooling such as air flows through refrigerant flow channel 4, rather than water cooling in which cooling water flows through refrigerant flow channel 4.

Capacitor module 1 is electrically connected to power module 2 through capacitor high-potential-side wiring member 31h and capacitor low-potential-side wiring member 31l. Capacitor high-potential-side wiring member 31h and capacitor low-potential-side wiring member 31l are connected to cooling body 3 with a thermally conductive insulating member 5 being interposed. Heat generated in capacitor element 12 is radiated to refrigerant flow channel 4 through thermally conductive insulating member 5 and cooling body 3. Consequently, capacitor element 12 is cooled. A material for thermally conductive insulating member 5 is, for example, silicone resin. A material for thermally conductive insulating member 5 may be a material obtained by incorporating a thermally conductive filler in a resin material.

As shown in FIGS. 4 and 5, capacitor module 1 is composed of a capacitor casing 11, capacitor element 12, capacitor high-potential-side wiring member 31h, capacitor low-potential-side wiring member 31l, and a capacitor sealing material 13. Capacitor element 12, capacitor high-potential-side wiring member 31h, capacitor low-potential-side wiring member 31l, and capacitor sealing material 13 are arranged in capacitor casing 11. Capacitor element 12 is arranged as lying between capacitor high-potential-side wiring member 31h and capacitor low-potential-side wiring member 31l.

Capacitor high-potential-side wiring member 31h is connected to capacitor element 12. Capacitor casing 11 is provided with a through hole H. Each of capacitor high-potential-side wiring member 31h and capacitor low-potential-side wiring member 31l extends from the inside of capacitor casing 11 to the outside through through hole H. As shown in FIG. 5, capacitor high-potential-side wiring member 31h extends to the outside of capacitor casing 11 through through hole H on the other end side located at the position opposite to one end connected to capacitor element 12. Capacitor high-potential-side wiring member 31h is connected to power module high-potential-side terminal portion 33h on the other end side located at the position opposite to one end connected to capacitor element 12. Capacitor low-potential-side wiring member 31l is connected to capacitor element 12. As shown in FIG. 4, capacitor low-potential-side wiring member 31l extends to the outside of capacitor casing 11 through through hole H on the other end side located at the position opposite to one end connected to capacitor element 12. Capacitor low-potential-side wiring member 31l is connected to power module low-potential-side terminal portion 331 on the other end side located at the position opposite to one end connected to capacitor element 12. Capacitor sealing material 13 seals capacitor element 12 and capacitor high-potential-side wiring member 31h and capacitor low-potential-side wiring member 31l except for a portion that extends to the outside of capacitor casing 11 so as to fill capacitor casing 11. For example, a polyethylene terephthalate (PET) resin material is employed as a material for capacitor casing 11. Since engineering plastics excellent in heat resistance may be employed as the material for capacitor casing 11, a polyphenylene sulfide (PPS) resin material and a polybutylene terephthalate (PBT) resin material other than the PET resin material may be employed.

Power module 2 is composed of switching elements 20 and 21, power module high-potential-side wiring member 32h, power module low-potential-side wiring member 32l, semiconductor element wiring members 34a, 34b, and 34c, an insulating member 25, a heat sink 26, a power module sealing material 23, and a power module casing 24. Though power module 2 is integrated with heat sink 26 in the present first embodiment, for example, power module 2 may be configured not to contain heat sink 26. In this case, power module 2 may be in such a structure that heat sink 26 is separately attached thereto. For example, the PET resin material is employed as a material for power module casing 24. Since engineering plastics excellent in heat resistance may be employed as the material for power module casing 24, a PPS resin material and a PBT resin material other than the PET resin material may be employed.

On the low potential side of power module 2, as shown in FIG. 4, low-potential-side IGBT element 21a and low-potential-side diode element 21d are arranged on an upper surface of semiconductor element wiring member 34c. Semiconductor element wiring member 34c is in surface connection to insulating member 25 at a surface opposite to a surface where low-potential-side IGBT element 21a and low-potential-side diode element 21d are arranged. Low-potential-side IGBT element 21a and low-potential-side diode element 21d are connected to power module low-potential-side wiring member 32l at a surface opposite to a surface connected to semiconductor element wiring member 34c. Low-potential-side diode element 21d has an anode connected to power module low-potential-side wiring member 32l and has a cathode connected to semiconductor element wiring member 34c. Low-potential-side IGBT element 21a has an emitter connected to power module low-potential-side wiring member 32l and has a collector connected to semiconductor element wiring member 34c. Power module low-potential-side wiring member 32l has power module low-potential-side terminal portion 33l that extends to the outside of power module casing 24 on the other end side located at a position opposite to one end connected to low-potential-side IGBT element 21a and low-potential-side diode element 21d.

On the high potential side of power module 2, as shown in FIG. 5, high-potential-side IGBT element 20a and high-potential-side diode element 20d are arranged on an upper surface of semiconductor element wiring member 34b. Semiconductor element wiring member 34b is in surface connection to insulating member 25 at a surface opposite to a surface where high-potential-side IGBT element 20a and high-potential-side diode element 20d are arranged. High-potential-side IGBT element 20a and high-potential-side diode element 20d are connected to semiconductor element wiring member 34a at a surface opposite to a surface connected to semiconductor element wiring member 34b. High-potential-side diode element 20d has a cathode connected to semiconductor element wiring member 34b and has an anode connected to semiconductor element wiring member 34a. High-potential-side IGBT element 20a has a collector connected to semiconductor element wiring member 34b and has an emitter connected to semiconductor element wiring member 34a. Semiconductor element wiring member 34b is connected to power module high-potential-side wiring member 32h at the surface where high-potential-side IGBT element 20a and high-potential-side diode element 20d are arranged. Power module high-potential-side wiring member 32h has power module high-potential-side terminal portion 33h that extends to the outside of power module casing 24 on the other end side located at a position opposite to one end connected to high-potential-side IGBT element 20a and high-potential-side diode element 20d.

At each of the high potential side and the low potential side, insulating member 25 is connected to heat sink 26 at a surface opposite to a surface where switching elements 20 and 21 are arranged. Heat sink 26 is mounted on cooling body 3 such that the surface opposite to the surface connected to insulating member 25 forms an inner wall of refrigerant flow channel 4 (to close refrigerant flow channel 4). Refrigerant flow channel 4 which is a hermetically sealed channel is thus formed. Cooling water or cooling air that flows through refrigerant flow channel 4 cools heat sink 26. Consequently, switching elements 20 and 21 are cooled through insulating member 25 and semiconductor element wiring members 34b and 34c.

Power module sealing material 23 seals switching elements 20 and 21, semiconductor element wiring members 34a, 34b, and 34c, and insulating member 25 so as to fill an area surrounded by power module casing 24 and heat sink 26. For example, a silicone gel material is employed as a material for power module sealing material 23.

As shown in FIGS. 2 to 5, power conversion device 100 according to the present first embodiment is characterized in that thermally conductive insulating member 5 is arranged such that thermal resistance of capacitor high-potential-side wiring member 31h and capacitor low-potential-side wiring member 31l in an area from capacitor module 1 to thermally conductive insulating member 5 is lower than thermal resistance of capacitor high-potential-side wiring member 31h and capacitor low-potential-side wiring member 31l in an area from power module 2 to thermally conductive insulating member 5.

Specifically, capacitor high-potential-side wiring member 31h and capacitor low-potential-side wiring member 31l each have a first contact portion 5a and a second contact portion 5b. As shown in FIGS. 4 and 5, portions where capacitor high-potential-side wiring member 31h and capacitor low-potential-side wiring member 31l pass through through hole H in capacitor casing 11 are defined as first contact portion 5a. Portions where capacitor high-potential-side wiring member 31h and capacitor low-potential-side wiring member 31l are connected to power module high-potential-side terminal portion 33h and power module low-potential-side terminal portion 33l, respectively, are defined as second contact portion 5b. A portion connected to thermally conductive insulating member 5 in each of capacitor high-potential-side wiring member 31h and capacitor low-potential-side wiring member 31l is defined as a third contact portion 5c. For example, third contact portion 5c may be a portion of the wiring member superimposed on a central portion of thermally conductive insulating member 5 in a direction along a direction of extension of capacitor high-potential-side wiring member 31h and capacitor low-potential-side wiring member 31l as shown in FIGS. 4 and 5. In a side view of power conversion device 100, in an example where cross-sectional shapes of capacitor high-potential-side wiring member 31h and capacitor low-potential-side wiring member 31l (shapes in a cross-section perpendicular to the direction of extension of capacitor high-potential-side wiring member 31h and capacitor low-potential-side wiring member 31l) from first contact portion 5a to second contact portion 5b are uniform, a distance L1 is set to be shorter than a distance L2. In this case, thermal resistance of capacitor high-potential-side wiring member 31h and capacitor low-potential-side wiring member 31l in the area from capacitor module 1 to thermally conductive insulating member 5 is lower than thermal resistance of capacitor high-potential-side wiring member 31h and capacitor low-potential-side wiring member 31l in the area from power module 2 to thermally conductive insulating member 5.

As shown in FIGS. 4 and 5, distance L1 refers to a distance along a surface of thermally conductive insulating member 5 from first contact portion 5a to third contact portion 5c in the side view of power conversion device 100. Distance L2 refers to a distance along the surface of thermally conductive insulating member 5 from second contact portion 5b to third contact portion 5c in the side view of power conversion device 100.

In the example where the cross-sectional shapes of capacitor high-potential-side wiring member 31h and capacitor low-potential-side wiring member 31l are uniform from first contact portion 5a to second contact portion 5b, thermally conductive insulating member 5 should only be arranged such that third contact portion 5c is located on a side of the capacitor relative to the point intermediate between first contact portion 5a and second contact portion 5b in each of capacitor high-potential-side wiring member 31h and capacitor low-potential-side wiring member 31l. The intermediate point is a point on the surface of each of capacitor high-potential-side wiring member 31h and capacitor low-potential-side wiring member 31l where distance L1 is equal to distance L2.

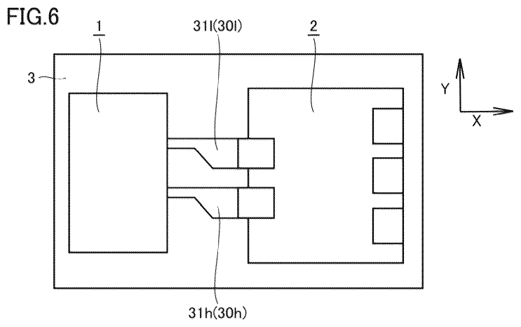

FIG. 6 is a plan view showing a modification of power conversion device 100 according to the present first embodiment. Though power conversion device 100 shown in FIG. 6 is basically similar in configuration to power conversion device 100 shown in FIGS. 1 to 5, it is different from power conversion device 100 shown in FIGS. 1 to 5 in that the cross-sectional shapes of capacitor high-potential-side wiring member 31h and capacitor low-potential-side wiring member 31l are not uniform. Specifically, as shown in FIG. 6, in a plan view where wiring member 30 is viewed from a direction perpendicular to the upper surface of cooling body 3, a width in a Y direction in the vicinity of first contact portion 5a in each of capacitor high-potential-side wiring member 31h and capacitor low-potential-side wiring member 31l is smaller than a width in the Y direction in the vicinity of second contact portion 5b. In the example where the cross-sectional shapes of capacitor high-potential-side wiring member 31h and capacitor low-potential-side wiring member 31l are thus not uniform from first contact portion 5a to second contact portion 5b, in consideration of Fourier's law which will be described later, thermally conductive insulating member 5 should only be arranged such that thermal resistance of capacitor high-potential-side wiring member 31h and capacitor low-potential-side wiring member 31l in the area from capacitor module 1 to thermally conductive insulating member 5 is lower than thermal resistance of capacitor high-potential-side wiring member 31h and capacitor low-potential-side wiring member 31l in the area from power module 2 to thermally conductive insulating member 5. A quantity of heat generated in capacitor element 12 and radiated to refrigerant flow channel 4 through thermally conductive insulating member 5 and cooling body 3 is thus increased. Consequently, capability to cool capacitor element 12 is improved. For example, in power conversion device 100 shown in FIG. 6, thermally conductive insulating member 5 may be arranged at a position closer to capacitor module 1 such that distance L1 is shorter than in power conversion device 100 shown in FIGS. 4 and 5. In the plan view shown in FIG. 6, the width in the Y direction in the vicinity of first contact portion 5a of each of capacitor high-potential-side wiring member 31h and capacitor low-potential-side wiring member 31l may be larger than the width in the Y direction in the vicinity of second contact portion 5b.

Considering a flow of heat as being similar to a flow of electricity, thermal resistance R (unit: K/W) of thermally conductive insulating member 5 in the present first embodiment can be expressed in an expression shown as an expression (1) below, based on the Fourier's law. A distance L (unit: m) represents a distance along the surface of wiring member 30. A cross-sectional area A (unit: m²) is a cross-sectional area of wiring member 30 in a cross-section perpendicular to a direction along the surface of wiring member 30. Thermal conductivity (unit: W/(m·K)) is a physical property value determined by a material for wiring member 30.

$$\begin{matrix}[ Math . 1 ] & \\ R = \frac{L}{kA} & ( 1 )\end{matrix}$$

A unction to coo capacitor element 12 in power conversion device 100 according to the present first embodiment will be described below.

In power conversion device 100 according to the present first embodiment, heat generated at the low potential side include heat Q21 generated in low-potential-side IGBT element 21a and low-potential-side diode element 21d with operations of low-potential-side IGBT element 21a and low-potential-side diode element 21d, Joule heat Q19 generated in power module low-potential-side wiring member 32l as a result of flow of a current from low-potential-side IGBT element 21a and low-potential-side diode element 21d, Joule heat Q15 generated in capacitor low-potential-side wiring member 31l as a result of flow of the current from low-potential-side IGBT element 21a and low-potential-side diode element 21d, and Joule heat Q12 generated in capacitor element 12 as a result of flow of the current from low-potential-side IGBT element 21a and low-potential-side diode element 21d.

Of heat Q21, a large quantity of heat is radiated to refrigerant flow channel 4 through semiconductor element wiring member 34c, insulating member 25, and heat sink 26. Remaining heat Q21 is radiated to refrigerant flow channel 4 through power module low-potential-side wiring member 32l, capacitor low-potential-side wiring member 31l, thermally conductive insulating member 5, and cooling body 3. Remaining heat Q21 radiated through thermally conductive insulating member 5 is defined as a quantity of heat Q211.

Of Joule heat Q19, a large quantity of heat is radiated to refrigerant flow channel 4 through low-potential-side IGBT element 21a and low-potential-side diode element 21d, semiconductor element wiring member 34c, insulating member 25, and heat sink 26. Remaining Joule heat Q19 is radiated to refrigerant flow channel 4 through capacitor low-potential-side wiring member 31l, thermally conductive insulating member 5, and cooling body 3. A quantity of heat of remaining Joule heat Q19 radiated through thermally conductive insulating member 5 is defined as a quantity of heat Q191.

A quantity of heat of Joule heat Q15 includes a quantity of heat radiated to refrigerant flow channel 4 through power module low-potential-side wiring member 32l, low-potential-side IGBT element 21a and low-potential-side diode element 21d, semiconductor element wiring member 34c, insulating member 25, and heat sink 26 and a quantity of heat radiated to refrigerant flow channel 4 through thermally conductive insulating member 5 and cooling body 3. Of Joule heat Q15, Joule heat Q15 radiated to refrigerant flow channel 4 through thermally conductive insulating member 5 and cooling body 3 is defined as a quantity of heat Q151.

To be exact, of Joule heat Q15, there is a quantity of heat radiated to refrigerant flow channel 4 through capacitor sealing material 13, capacitor casing 11, and cooling body 3. A copper material contained in capacitor low-potential-side wiring member 31l has thermal conductivity of 398 W/(m·K), whereas an epoxy resin material contained in capacitor sealing material 13 and a PET resin material contained in capacitor casing 11 have thermal conductivity of 0.2 W/(m·K) and thermal conductivity of 0.3 W/(m·K) which are relatively low, respectively. Therefore, the quantity of heat radiated to refrigerant flow channel 4 through capacitor sealing material 13, capacitor casing 11, and cooling body 3 is ignorably smaller than quantity of heat Q151, and hence it is not taken into account.

Joule heat Q12 is radiated to refrigerant flow channel 4 through capacitor low-potential-side wiring member 31l, thermally conductive insulating member 5, and cooling body 3. A quantity of heat of this Joule heat Q15 is defined as quantity of heat Q151. To be exact, of Joule heat Q12, there is a quantity of heat radiated to refrigerant flow channel 4 through capacitor sealing material 13, capacitor casing 11, and cooling body 3. Similarly to Joule heat Q15, however, the quantity of heat radiated to refrigerant flow channel 4 through capacitor sealing material 13, capacitor casing 11, and cooling body 3 is ignorably small, and hence it is not taken into account.

Joule heat Q12, Joule heat Q15, and Joule heat Q19 described above and heat Q21 include the quantities of heat radiated to ambient air through capacitor casing 11 or power module casing 24. In consideration of thermal conductivity and a coefficient of convection heat transfer of a constituent material, however, the quantity of heat radiated to ambient air through capacitor casing 11 or power module casing 24 is ignorably small, and hence it is not taken into account.

As set forth above, a sum Q1 of the quantities of heat that passes through the thermally conductive insulating member at the low potential side in power conversion device 100 according to the present first embodiment is expressed in an expression shown in an expression (2) below.

[Math. 2]

Q1=Q211+Q191+Q151+Q121 (2)

The configuration at the high potential side in power conversion device 100 according to the present first embodiment is different from the configuration at the low potential side in that capacitor high-potential-side wiring member 31h is connected to the upper surface of capacitor element 12 (the surface located at a position opposite to cooling body 3 when viewed from capacitor element 12) and that power module high-potential-side wiring member 32h is connected to semiconductor element wiring member 34b rather than switching elements 20 and 21. Since the configuration at the high potential side is the same as the configuration at the low potential side except for two points described above, the cooling function at the high potential side is similar to the cooling function at the low potential side.

Of heat generated in high-potential-side IGBT element 20a and high-potential-side diode element 20d with operations of high-potential-side IGBT element 20a and high-potential-side diode element 20d, the quantity of heat radiated to refrigerant flow channel 4 through semiconductor element wiring member 34b, power module high-potential-side wiring member 32h, capacitor high-potential-side wiring member 31h, thermally conductive insulating member 5, and cooling body 3 is defined as a quantity of heat Q202.

Of Joule heat generated in power module high-potential-side wiring member 32h, a quantity of heat radiated to refrigerant flow channel 4 through capacitor high-potential-side wiring member 31h, thermally conductive insulating member 5, and cooling body 3 is defined as a quantity of heat Q182.

Of Joule heat generated in capacitor high-potential-side wiring member 31h, a quantity of heat radiated to refrigerant flow channel 4 through thermally conductive insulating member 5 and cooling body 3 is defined as a quantity of heat Q142.

Of Joule heat Q12 generated in capacitor element 12, a quantity of heat of Joule heat Q12 radiated to refrigerant flow channel 4 through capacitor high-potential-side wiring member 31h, thermally conductive insulating member 5, and cooling body 3 is defined as a quantity of heat Q122.

As set forth above, a sum Q2 of the quantities of heat that passes through the thermally conductive insulating member at the high potential side in power conversion device 100 according to the present first embodiment is expressed in an expression shown in an expression (3) below.

[Math. 3]

Q2=Q202+Q182+Q142+Q122 (3)

### <Functions and Effects>

Power conversion device 100 according to the present disclosure includes capacitor element 12, switching element 20, 21, wiring member 30, cooling body 3, and thermally conductive insulating member 5. Wiring member 30 is electrically connected to capacitor element 12 and switching element 20, 21. On cooling body 3, capacitor element 12 and switching element 20, 21 are mounted. Thermally conductive insulating member 5 is connected to cooling body 3 and wiring member 30. Wiring member 30 has first contact portion 5a and second contact portion 5b. Wiring member 30 is connected to capacitor element 12 at first contact portion 5a. Wiring member 30 is connected to switching element 20, 21 at second contact portion 5b. Thermal resistance of wiring member 30 in the area from first contact portion 5a to thermally conductive insulating member 5 is lower than thermal resistance of wiring member 30 in the area from second contact portion 5b to thermally conductive insulating member 5.

Thus, the thermal resistance of wiring member 30 in the area from first contact portion 5a to thermally conductive insulating member 5 is lower than the thermal resistance of wiring member 30 in the area from second contact portion 5b to thermally conductive insulating member 5, and hence heat generated in capacitor element 12 can effectively be transferred to cooling body 3 through wiring member 30 and thermally conductive insulating member 5. Therefore, increase in temperature of capacitor element 12 by heat Q12 generated in capacitor element 12 can be suppressed. An amount of increase in temperature of thermally conductive insulating member 5 by heat Q20 and heat Q21 generated in switching elements 20 and 21, heat Q19 generated in power module low-potential-side wiring member 32l, and heat Q18 generated in power module high-potential-side wiring member 32h, on the other hand, is small. Consequently, since increase in temperature of capacitor element 12 due to increase in temperature of thermally conductive insulating member 5 can be suppressed, increase in temperature of capacitor element 12 can consequently be suppressed.

In power conversion device 100, with a portion of wiring member 30 connected to thermally conductive insulating member 5 being defined as third contact portion 5c, distance L1 from first contact portion 5a to third contact portion 5c is shorter than distance L2 from second contact portion 5b to third contact portion 5c.

Thus, in an example where wiring member 30 is uniform in cross-sectional shape, the thermal resistance of wiring member 30 in the area from first contact portion 5a to thermally conductive insulating member 5 is lower than the thermal resistance of wiring member 30 in the area from second contact portion 5b to thermally conductive insulating member 5, and hence increase in temperature of capacitor element 12 can be suppressed.

In power conversion device 100, refrigerant flow channel 4 is provided in cooling body 3 at a position opposed to switching elements 20 and 21. In this case, heat transferred from thermally conductive insulating member 5 to cooling body 3 can effectively be removed by refrigerant that flows through refrigerant flow channel 4 and switching elements 20 and 21 can efficiently be cooled.

Simulation as below was conducted to verify the effects of power conversion device 100 according to the present first embodiment as above.

### <Analysis Condition>

Increase in temperature of the capacitor element when a power conversion device as a first example configured similarly to power conversion device 100 shown in FIGS. 1 to 5 operated, with temperatures of low-potential-side IGBT element 21a and low-potential-side diode element 21d and temperatures of semiconductor element wiring member 34b and cooling body 3 being set to 120 °C, 120 °C, 80 °C, and 70 °C, respectively and with the position of the thermally conductive insulating member being varied, was obtained by simulation. A ripple current that flowed from power module 2 to capacitor module 1 was set to 200 Arms.

### <Results of Analysis>

Table 1 shows results of simulation in the first example under the analysis condition above. In Table 1, a ratio of the position of thermally conductive insulating member 5 is expressed by a value calculated by dividing distance L1 from first contact portion 5a to third contact portion 5c by the distance (distance L1+distance L2) from first contact portion 5a to second contact portion 5b. As can be seen in Table 1, the ratio of the position of thermally conductive insulating member 5 being lower than 50% is lower in temperature of capacitor element 12 after stabilization in the first example than the ratio of the position of thermally conductive insulating member 5 being equal to or higher than 50%. In other words, when the cross-sectional shape of wiring member 30 is uniform, arrangement of thermally conductive insulating member 5 at the position closer to first contact portion 5a than second contact portion 5b can suppress increase in temperature of capacitor element 12.

TABLE 1

| | Ratio of Position Of Thermally | | | | |
|---|---|---|---|---|---|
| | Conductive Insulating Member 5 | | | | |
| | 16% | 33% | 50% | 66% | 83% |
| Temperature | 101 °C | 105 °C | 109 °C | 113 °C | 118 °C |
| of Capacitor | | | | | |
| Element 12 | | | | | |
| After | | | | | |
| Stabilization | | | | | |

### Second Embodiment

### <Configuration of Power Conversion Device>

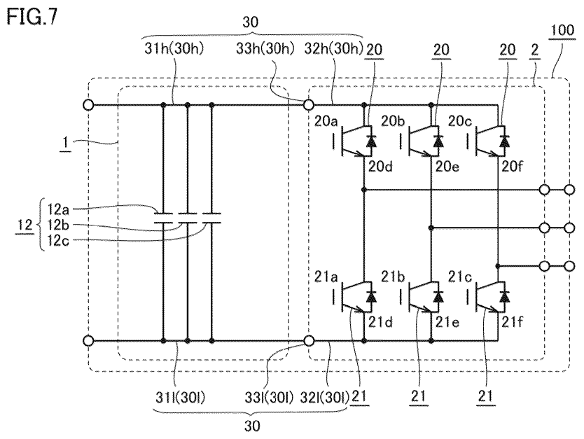

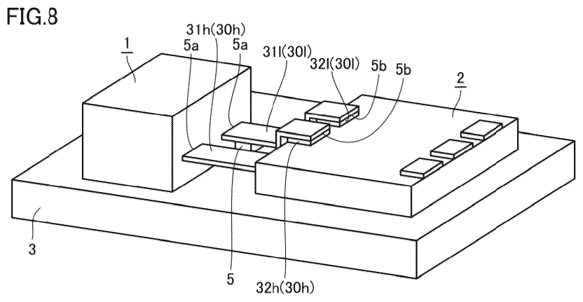

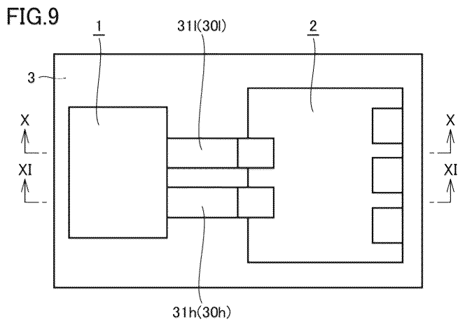

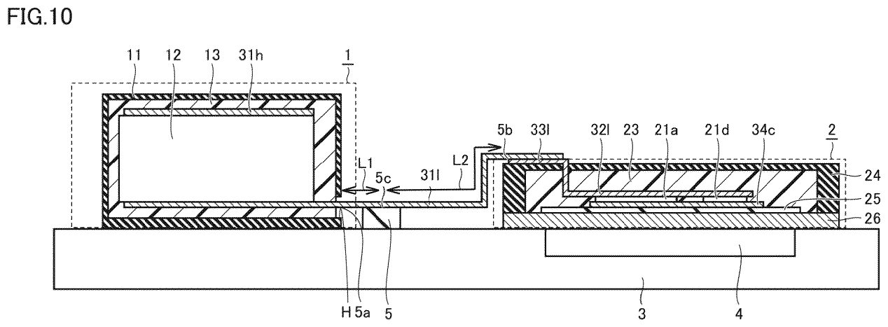

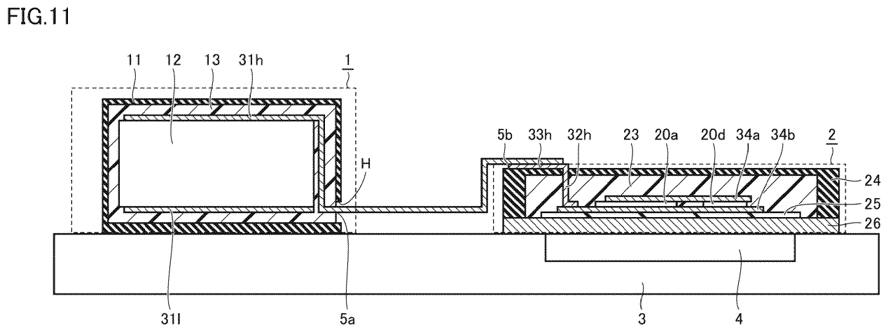

FIG. 7 is a circuit diagram of power conversion device 100 according to a second embodiment. FIG. 7 corresponds to FIG. 1. FIG. 8 is a perspective view of power conversion device 100 according to the second embodiment. FIG. 8 corresponds to FIG. 2. FIG. 9 is a plan view of power conversion device 100 according to the second embodiment. FIG. 9 corresponds to FIG. 3. FIG. 10 is a cross-sectional view along a line segment X-X in FIG. 9. FIG. 10 corresponds to FIG. 4. FIG. 11 is a cross-sectional view along a line segment XI-XI in FIG. 9. FIG. 11 corresponds to FIG. 5.

Though power conversion device 100 shown in FIGS. 7 to 11 is basically similar in configuration to power conversion device 100 shown in FIGS. 1 to 5, it is different from power conversion device 100 shown in FIGS. 1 to 5 in that thermally conductive insulating member 5 is not provided at the high potential side. A circuit of power conversion device 100 shown in FIG. 7 is different from the circuit of power conversion device 100 shown in FIG. 1 in that three capacitor elements 12 are provided.

Power conversion device 100 according to the present second embodiment may be designed in conformity with an example where the ripple current that flows through capacitor module 1 is low. Since the ripple current that flows through capacitor module 1 is low, for example, three capacitor elements 12 may be connected in parallel in capacitor module 1. In the present second embodiment, in conformity with three capacitor elements 12, capacitor module 1 in the present second embodiment can be smaller in outer geometry than capacitor module 1 in the first embodiment. Since the ripple current that flows through capacitor module 1 is low, capacitor high-potential-side wiring member 31h and capacitor low-potential-side wiring member 31l in the present second embodiment may be smaller in cross-sectional area than capacitor high-potential-side wiring member 31h and capacitor low-potential-side wiring member 31l in the first embodiment, and may be smaller, for example, by 38%.

In power conversion device 100 in the present second embodiment, the ripple current is low. Therefore, resistance loss that occurs in each of capacitor element 12, capacitor high-potential-side wiring member 31h, power module high-potential-side wiring member 32h, power module low-potential-side wiring member 32l, and capacitor low-potential-side wiring member 31l where the ripple current flows is low. Therefore, thermally conductive insulating member 5 is arranged only at the low potential side in the present second embodiment.

A structure in power module 2 at the high potential side is such that, when viewed from heat sink 26, insulating member 25, semiconductor element wiring member 34b, and high-potential-side IGBT element 20a and high-potential-side diode element 20d are two-dimensionally joined in this order. Power module high-potential-side wiring member 32h is also joined to semiconductor element wiring member 34b.

The structure in power module 2 at the low potential side, on the other hand, is such that, when viewed from heat sink 26, insulating member 25, semiconductor element wiring member 34c, and low-potential-side IGBT element 21a and low-potential-side diode element 21d are two-dimensionally joined in this order. Therefore, low-potential-side IGBT element 21a and low-potential-side diode element 21d are higher in temperature than semiconductor element wiring member 34c. Consequently, power module low-potential-side wiring member 32l connected to low-potential-side IGBT element 21a and low-potential-side diode element 21d is higher in temperature than power module high-potential-side wiring member 32h connected to semiconductor element wiring member 34b. Therefore, performance to cool capacitor element 12 can more effectively be improved by connection of thermally conductive insulating member 5 to power module low-potential-side wiring member 32l than by connection to power module high-potential-side wiring member 32h.

Thus, attachment of thermally conductive insulating member 5 at only one location will suffice, and the structure of power conversion device 100 according to the present second embodiment is simplified.

### <Functions and Effects>

In power conversion device 100, wiring member 30 is connected to the surface of each of switching elements 20 and 21 opposite to the surface opposed to cooling body 3. Thermally conductive insulating member 5 is connected only to cooling body 3 and wiring member 30. Thus, even when wiring member 30 is connected to the surface of each of switching elements 20 and 21 opposite to the surface opposed to cooling body 3, heat generated in switching elements 20 and 21 can be radiated to cooling body 3 through thermally conductive insulating member 5. Consequently, since increase in temperature of capacitor element 12 by heat generated in switching elements 20 and 21 can be suppressed, performance to cool capacitor element 12 can consequently be improved.

In power conversion device 100, switching elements 20 and 21 include high-potential-side switching element 20 and low-potential-side switching element 21. Wiring member 30 includes high-potential-side wiring member 30h and low-potential-side wiring member 30l High-potential-side wiring member 30h is connected to the surface of high-potential-side switching element 20 opposed to cooling body 3. Low-potential-side wiring member 30l is connected to the surface of low-potential-side switching element 21 opposite to the surface opposed to cooling body 3. Thermally conductive insulating member 5 is connected only to cooling body 3 and low-potential-side wiring member 30l. Thus, even when there are a plurality of wiring members 30 that connect capacitor element 12 to switching elements 20 and 21, thermally conductive insulating member 5 does not have to be attached to all wiring members 30 and the number of components included in power conversion device 100 can be reduced. Consequently, the structure of power conversion device 100 can be simplified.

Simulation as below was conducted to verify the effects of power conversion device 100 according to the present second embodiment as above.

### <Analysis Condition>

Increase in temperature of the capacitor element when power conversion devices in a second example and a third example operated, with temperatures of low-potential-side IGBT element 21a and low-potential-side diode element 21d and temperatures of semiconductor element wiring member 34b and cooling body 3 being set to 120 °C, 120 °C, 80 °C, and 70 °C, respectively and with the position of the thermally conductive insulating member being varied, was obtained by simulation. A ripple current that flowed from power module 2 to capacitor module 1 was set to 100 Arms. The second example is configured similarly to power conversion device 100 according to the present second embodiment, and thermally conductive insulating member 5 is arranged only on the low potential side. The third example has such a structure that thermally conductive insulating member 5 is not arranged on the low potential side but arranged only on the high potential side.

### <Results of Analysis>

Table 2 shows results of simulation under conditions above.

TABLE 2

| | | Ratio of Position of Thermally | | | | |
|---|---|---|---|---|---|---|
| | | Conductive Insulating Member 5 | | | | |
| | | 16% | 33% | 50% | 66% | 83% |
| Temperature | Example 2 | 102 °C | 105 °C | 108 °C | 112 °C | 115 °C |
| of Capacitor | Example 3 | 118 °C | 122 °C | 126 °C | 129 °C | 132 °C |
| Element 12 | | | | | | |
| After | | | | | | |
| Stabilization | | | | | | |

As can be seen in Table 2, the temperature of capacitor element 12 after settling in the second example is lower than the temperature of capacitor element 12 after settling in the third example in comparison at any ratio of the position of thermally conductive insulating member 5. In each of the second example and the third example, the temperature of capacitor element 12 after stabilization is relatively lower in the example where the ratio of the position of thermally conductive insulating member 5 is lower than 50% than in the example where the ratio of the position of thermally conductive insulating member 5 is equal to or higher than 50%. This is the same as the results of simulation in power conversion device 100 according to the first embodiment.

### Third Embodiment

### <Configuration of Power Conversion Device>

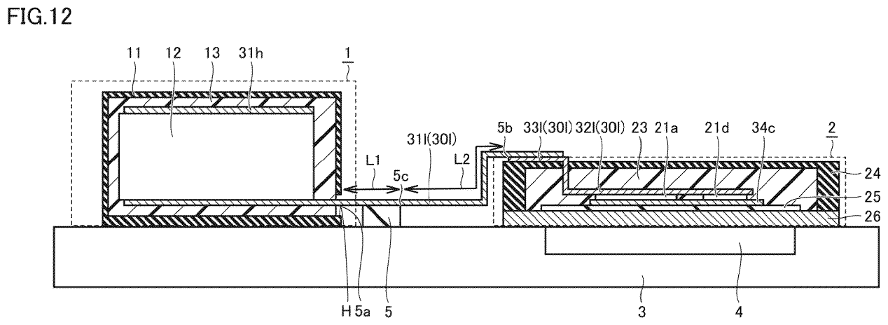

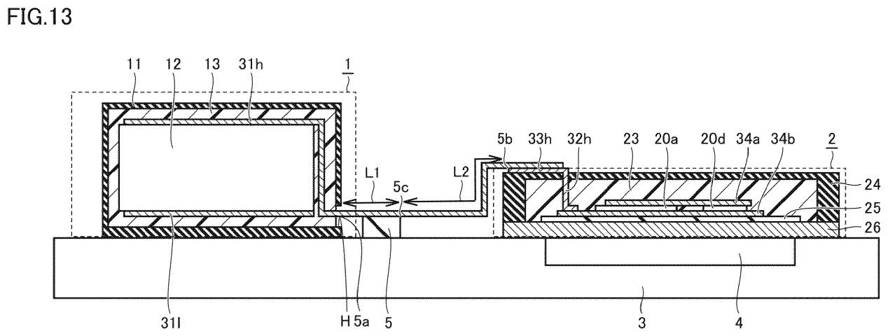

FIGS. 12 and 13 are cross-sectional views of power conversion device 100 according to a third embodiment. FIG. 12 corresponds to FIG. 4. FIG. 13 corresponds to FIG. 5.

Though power conversion device 100 shown in FIGS. 12 and 13 is basically similar in configuration to power conversion device 100 shown in FIGS. 1 to 5, it is different from power conversion device 100 shown in FIGS. 1 to 5 in that the entire thermally conductive insulating member 5 is located on the side of the capacitor relative to a point intermediate between first contact portion 5a and second contact portion 5b. Specifically, as shown in FIGS. 12 and 13, third contact portion 5c is a portion of the wiring member superimposed on one end of thermally conductive insulating member 5 (a point distant from first contact portion 5a) in the direction along the direction of extension of capacitor high-potential-side wiring member 31h and capacitor low-potential-side wiring member 31l.

Third contact portion 5c may be arranged on the side of capacitor element 12 relative to the point intermediate between first contact portion 5a and second contact portion 5b. In other words, opposing ends of thermally conductive insulating member 5 may be arranged on the side of the capacitor relative to the point intermediate between first contact portion 5a and second contact portion 5b in the direction along the direction of extension of capacitor high-potential-side wiring member 31h and capacitor low-potential-side wiring member 31l.

Since thermally conductive insulating member 5 is thus arranged on the side of capacitor element 12, increase in temperature of capacitor element 12 can further be suppressed.

### <Functions and Effects>

In power conversion device 100, the entire thermally conductive insulating member 5 is located on the side of capacitor element 12 relative to the point intermediate between first contact portion 5a and second contact portion 5b. Increase in temperature of capacitor element 12 can thus further be suppressed.

### Fourth Embodiment

### <Configuration of Power Conversion Device>

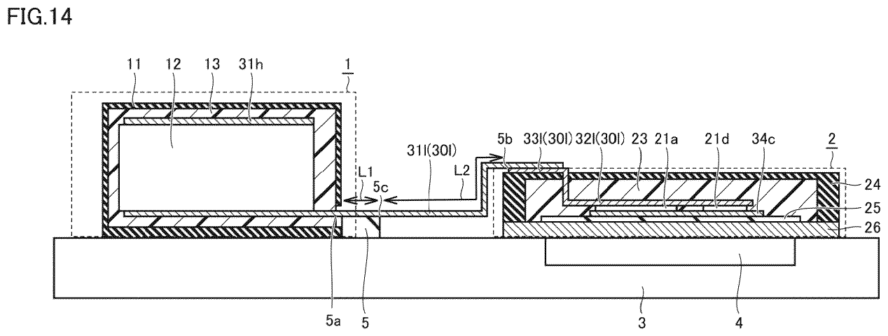

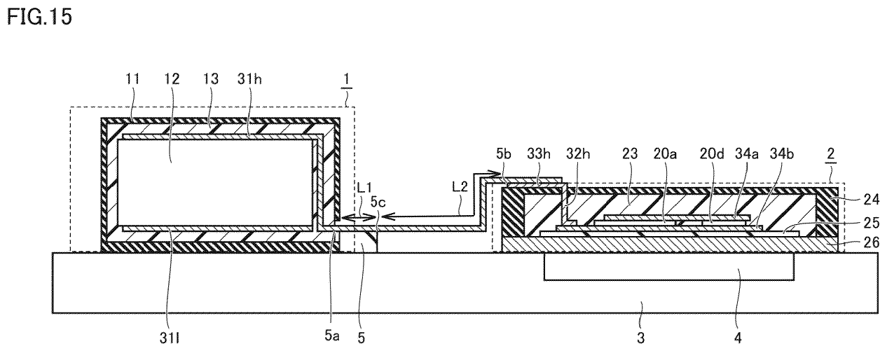

FIGS. 14 and 15 are cross-sectional views of power conversion device 100 according to a fourth embodiment. FIG. 14 corresponds to FIG. 4. FIG. 15 corresponds to FIG. 5.

Though power conversion device 100 shown in FIGS. 14 and 15 is basically similar in configuration to power conversion device 100 shown in FIGS. 1 to 5, it is different from power conversion device 100 shown in FIGS. 1 to 5 in that thermally conductive insulating member 5 is in contact with capacitor element 12. Specifically, thermally conductive insulating member 5 is in contact with a side surface of capacitor casing 11 and hence thermally conductive insulating member 5 is in indirect contact with capacitor element 12. Capacitor module 1 may be composed of capacitor element 12, capacitor high-potential-side wiring member 31h, and capacitor low-potential-side wiring member 31l, and thermally conductive insulating member 5 may be in direct contact with capacitor element 12.

Since thermally conductive insulating member 5 is thus arranged on the side of capacitor element 12, increase in temperature of capacitor element 12 can further be suppressed.

### <Functions and Effects>

In power conversion device 100, thermally conductive insulating member 5 is in contact with capacitor element 12. Increase in temperature of capacitor element 12 can thus further be suppressed.

It should be understood that the embodiments disclosed herein are illustrative and non-restrictive in every respect. At least two of the embodiments disclosed herein may be combined unless there is inconsistency. The basic scope of the present disclosure is defined by the terms of the claims rather than the description above and is intended to include any modifications within the scope and meaning equivalent to the terms of the claims.

Various manners of the present disclosure will be described below as being summarized as additional aspects.

### (Additional Aspect 1)

A power conversion device includes
a capacitor element,
a switching element,
a wiring member electrically connected to the capacitor element and the switching element,
a cooling body on which the capacitor element and the switching element thereon are mounted, and
a thermally conductive insulating member connected to the cooling body and the wiring member,
the wiring member has a first contact portion and a second contact portion,
the wiring member is connected to the capacitor element at the first contact portion,
the wiring member is connected to the switching element at the second contact portion, and
thermal resistance of the wiring member in an area from the first contact portion to the thermally conductive insulating member is lower than thermal resistance of the wiring member in an area from the second contact portion to the thermally conductive insulating member.

### (Additional Aspect 2)

In the power conversion device according to Additional Aspect 1,
with a portion of the wiring member connected to the thermally conductive insulating member being defined as a third contact portion,
a distance from the first contact portion to the third contact portion is shorter than a distance from the second contact portion to the third contact portion.

### (Additional Aspect 3)

In the power conversion device according to Additional Aspect 1 or 2,
the wiring member is connected to a surface of the switching element opposite to a surface opposed to the cooling body, and
the thermally conductive insulating member is connected only to the cooling body and the wiring member.

### (Additional Aspect 4)

In the power conversion device according to Additional Aspect 1 or 2,
the switching element includes a high-potential-side switching element and a low-potential-side switching element,
the wiring member includes a high-potential-side wiring member and a low-potential-side wiring member,
the high-potential-side wiring member is connected to a surface of the high-potential-side switching element opposed to the cooling body,
the low-potential-side wiring member is connected to a surface of the low-potential-side switching element opposite to a surface opposed to the cooling body, and
the thermally conductive insulating member is connected only to the cooling body and the low-potential-side wiring member.

### (Additional Aspect 5)

In the power conversion device according to any one of Additional Aspects 1 to 4,
a refrigerant flow channel is provided in the cooling body at a position opposed to the switching element.

### (Additional Aspect 6)

In the power conversion device according to any one of Additional Aspects 1 to 5,
the entirety of the thermally conductive insulating member is located on a side of the capacitor element relative to a point intermediate between the first contact portion and the second contact portion.

### (Additional Aspect 7)

In the power conversion device according to any one of Additional Aspects 1 to 6,
the thermally conductive insulating member is in contact with the capacitor element.

### REFERENCE SIGNS LIST

1 capacitor module; 2 power module; 3 cooling body; 4 refrigerant flow channel; 5 thermally conductive insulating member; 5a first contact portion; 5b second contact portion; 5c third contact portion; 11 capacitor casing; 12 capacitor element; 13 capacitor sealing material; 20, 21 switching element; 20 high-potential-side switching element; 20a high-potential-side IGBT element; 20d high-potential-side diode element; 21 low-potential-side switching element; 21a low-potential-side IGBT element; 21d low-potential-side diode element; 23 power module sealing material; 24 power module casing; 25 insulating member; 26 heat sink; 30 wiring member; 30h high-potential-side wiring member; 30l low-potential-side wiring member; 31h capacitor high-potential-side wiring member; 31l capacitor low-potential-side wiring member; 32h power module high-potential-side wiring member; 32l power module low-potential-side wiring member; 33h power module high-potential-side terminal portion; 331 power module low-potential-side terminal portion; 34a, 34b, 34c semiconductor element wiring member; 100 power conversion device; L, L1, L2 distance; H through hole.

1. A power conversion device comprising:
a capacitor element;
a switching element;
a wiring member electrically connected to the capacitor element and the switching element;
a cooling body; and
a thermally conductive insulating member connected to the cooling body and the wiring member, wherein
the wiring member has a first contact portion and a second contact portion,
the wiring member is connected to the capacitor element at the first contact portion,
the wiring member is connected to the switching element at the second contact portion, and
thermal resistance of the wiring member in an area from the first contact portion to the thermally conductive insulating member is lower than thermal resistance of the wiring member in an area from the second contact portion to the thermally conductive insulating member.

2. The power conversion device according to claim 1, wherein
with a portion of the wiring member connected to the thermally conductive insulating member being defined as a third contact portion,
a distance from the first contact portion to the third contact portion is shorter than a distance from the second contact portion to the third contact portion.

3. The power conversion device according to claim 1, wherein
the wiring member is connected to a surface of the switching element opposite to a surface opposed to the cooling body, and
the thermally conductive insulating member is connected only to the cooling body and the wiring member.

4. The power conversion device according to claim 1, wherein
the switching element comprises a high-potential-side switching element and a low-potential-side switching element,
the wiring member comprises a high-potential-side wiring member and a low-potential-side wiring member,
the high-potential-side wiring member is connected to a surface of the high-potential-side switching element opposed to the cooling body,
the low-potential-side wiring member is connected to a surface of the low-potential-side switching element opposite to a surface opposed to the cooling body, and
the thermally conductive insulating member is connected only to the cooling body and the low-potential-side wiring member.

5. The power conversion device according to claim 1, wherein
a refrigerant flow channel is provided in the cooling body at a position opposed to the switching element.

6. The power conversion device according to claim 1, wherein
entirety of the thermally conductive insulating member is located on a side of the capacitor element relative to a point intermediate between the first contact portion and the second contact portion.

7. The power conversion device according to claim 1, wherein
the thermally conductive insulating member is in contact with the capacitor element.

8. The power conversion device according to claim 1, wherein the switching element is mounted on the cooling body.

9. The power conversion device according to claim 8, wherein the capacitor element is mounted on the cooling body.

10. The power conversion device according to claim 2, wherein the wiring member is connected to a surface of the switching element opposite to a surface opposed to the cooling body, and
the thermally conductive insulating member is connected only to the cooling body and the wiring member.

11. The power conversion device according to claim 2, wherein the switching element comprises a high-potential-side switching element and a low-potential-side switching element,
the wiring member comprises a high-potential-side wiring member and a low potential-side wiring member,
the high-potential-side wiring member is connected to a surface of the high-potential-side switching element opposed to the cooling body,
the low-potential-side wiring member is connected to a surface of the low potential-side switching element opposite to a surface opposed to the cooling body, and
the thermally conductive insulating member is connected only to the cooling body and the low-potential-side wiring member.

12. The power conversion device according to claim 2, wherein a refrigerant flow channel is provided in the cooling body at a position opposed to the switching element.

13. The power conversion device according to claim 2, wherein entirety of the thermally conductive insulating member is located on a side of the capacitor element relative to a point intermediate between the first contact portion and the second contact portion.

14. The power conversion device according to claim 2, wherein the thermally conductive insulating member is in contact with the capacitor element.
